(19) United States
(12) Patent Application Publication
(10) Pub. No.: US 2016/0343593 A1
(43) Pub. Date: Nov. 24, 2016

(54) SEMICONDUCTOR PACKAGE INCLUDING PREMOLD AND METHOD OF MANUFACTURING THE SAME

(71) Applicant: Amkor Technology Inc., Tempe, AZ (US)

(72) Inventors: Dong Hee Kang, Kyunggi-do (KR); Kyu Won Lee, Seoul (KR); Jae Yoon Kim, Seoul (KR)

(73) Assignee: Amkor Technology, Inc., Tempe, AZ (US)

(21) Appl. No.: 15/202,245

(22) Filed: Jul. 5, 2016

Related U.S. Application Data
(63) Continuation of application No. 11/382,615, filed on May 10, 2006.

(51) Int. Cl. H01L 21/56; H01L 21/48; H01L 21/78; H01L 21/683; H01L 23/00

(52) U.S. Cl. CPC H01L 21/565; H01L 21/6835; H01L 24/09; H01L 21/78; H01L 21/4853; H01L 2224/48091

(57) ABSTRACT

A semiconductor package including a premold which is used to define support structure for a semiconductor die which is mounted to the premold by a layer of suitable adhesive. Embedded within the premold are lands which each include oppose upper and lower surfaces exposed in respective ones of upper and lower surfaces define by the premold. The semiconductor die, which is attached to the upper surface of the premold by the adhesive layer, is electrically connected to the exposed upper surfaces of the lands through the use of conductive wires. The semiconductor die, conductive wires, and the upper surface of the premold are covered or encapsulated by a package body. The package body does not cover any portion of the lower surface of the premold, thus allowing the exposed lower surfaces of the lands to be placed into electrical connection or communication with an underlying substrate such as a PCB or motherboard.

### CROSS-REFERENCE TO RELATED APPLICATIONS

The present application is a continuation of U.S. application Ser. No. 11/382,615 entitled SEMICONDUCTOR PACKAGE INCLUDING PREMOLD AND METHOD OF MANUFACTURING THE SAME filed May 10, 2006, which is incorporated herein by reference in its entirety to provide continuity of disclosure.

### STATEMENT RE: FEDERALLY SPONSORED RESEARCH/DEVELOPMENT

Not Applicable

### BACKGROUND

The present invention relates generally to semiconductor packages, and more particularly to an LGA-type semiconductor package which is fabricated to include a premold and is devoid of a die attach pad (also referred to as a die pad) to reduce the overall thickness of the semiconductor package, and to a method of manufacturing such semiconductor package.

Semiconductor dies are conventionally enclosed in plastic packages that provide protection from hostile environments and enable electrical interconnection between the semiconductor die and an underlying substrate such as a printed circuit board (PCB) or motherboard. The elements of such a package include a metal leadframe, an integrated circuit or semiconductor die, bonding material to attach the semiconductor die to the leadframe, bond wires which electrically connect pads on the semiconductor die to individual leads of the leadframe, and a hard plastic encapsulant material which covers the other components and forms the exterior of the semiconductor package commonly referred to as the package body.

The leadframe is the central supporting structure of such a package, and is typically fabricated by chemically etching or mechanically stamping a metal strip. A portion of the leadframe is internal to the package, i.e. completely surrounded by the plastic encapsulant or package body. Portions of the leads of the leadframe extend externally from the package body or are partially exposed therein for use in electrically connecting the package to another component.

In the electronics industry, hand held portable and compact electronic devices such as cellular phones, digital video camcorders, digital cameras, and laptop computers require semiconductor packages which are progressively smaller and lighter, yet of increasing performance. To address this particular need, there has been developed in the prior art ultra-compact semiconductor packages such as Chip Size Packages (CSP's) and Wafer Level Chip Size Packages (WLCSP's). Another type of semiconductor package which has been developed to address such need is referred to as a Land Grid Array (LGA) semiconductor package. LGA semiconductor packages as currently known typically include lands arrayed on a lower surface of a substrate for connection to a motherboard. More particularly, LGA semiconductor packages usually include a substrate, a semiconductor die attached to the substrate by an adhesive, an encapsulant for covering or enclosing the semiconductor die and the substrate, and one or more lands formed on a surface of the substrate which is to be mounted to the motherboard or other external device. Since the LGA semiconductor package has a land directly mounted to a motherboard or other external device rather than a solder ball, the process for thermally attaching a solder ball to the LGA semiconductor package can be omitted from the manufacturing process related thereto, thus saving on the manufacturing cost. The substrate of the LGA semiconductor package may be made from any one of a leadframe, a printed circuit board or PCB, circuit film, and circuit tape.

When the substrate of an LGA semiconductor package is made of a leadframe or adhesive film, the manufacture of the LGA semiconductor package is generally completed by initially attaching the adhesive film to a carrier, such carrier acting as a support during the fabrication process. A die attach pad (DAP) or die pad and a lead are then attached to the upper surface of the adhesive film, with a semiconductor die then being attached to the upper surface of the die pad through the use of an adhesive. The semiconductor die and lead are electrically connected to each other through the use of, for example, a conductive wire. An encapsulation step is then completed to form the package body of the LGA semiconductor package, such fully formed package body covering both the semiconductor die, the conductive wire and at least portions of the die pad and lead. Subsequent to the formation of the package body, the adhesive film is removed. The die pad of the LGA semiconductor package makes a large contribution to heat emission from the semiconductor die attached thereto, and also may provide a ground function. However, the elimination of the die pad allows the LGA semiconductor package to be fabricated with substantially reduced thickness, which is desirable as a result of the trends described above.

However, a number of problems typically occur when a leadframe without a die pad is used as the substrate of an LGA semiconductor package. Firstly, when the adhesive is directly applied to adhesive film without a die pad, a semiconductor die is attached to the film by the adhesive, the encapsulation is step is completed, and the film is thereafter removed, the adhesion between the adhesive and the adhesive film makes it difficult to secure satisfactory peeling properties. Secondly, although the die pad is omitted to reduce the thickness of the LGA semiconductor package, stress acting on the adhesive when the film is removed may degrade the reliability of the completed LGA semiconductor package. In addition, the lower surface of the completed LGA semiconductor package may fail to be smooth or substantially planar, thus imparting a non-uniform thickness to the LGA semiconductor package which is also undesirable.

The present invention addresses and overcomes these deficiencies by providing an LGA semiconductor package which is fabricated to include a premold and is devoid of a die pad to reduce the overall thickness of the semiconductor package. These and other features of the present invention will be described in more detail below. cl BRIEF SUMMARY

In accordance with the present invention, there is provided multiple embodiments of a semiconductor package which is fabricated to include a premold and is devoid of a die attach pad or die pad to reduce the overall thickness of the semiconductor package. More particularly, in each embodiment of the present invention, a premold is used to define a support structure for a semiconductor die which is mounted to the premold by a layer of a suitable adhesive. Embedded within the premold are lands which each include opposed upper and lower surfaces exposed in respective ones of upper and lower surfaces defined by the premold. The semiconductor die, which is attached to the upper surface of the premold by the adhesive layer, is electrically connected to the exposed upper surfaces of the lands through the use of conductive wires. The semiconductor die, conductive wires, and the upper surface of the premold (including the upper surfaces of the lands) are covered or encapsulated by a package body. The package body does not cover any portion of the lower surface of the premold, thus allowing the exposed lower surfaces of the lands to be placed into electrical connection or communication with an underlying substrate such as a PCB or motherboard. Due to its inclusion of the premold, the semiconductor package may be fabricated without a die pad thus reducing the overall thickness thereof, yet is not susceptible to many of the above-described potential structural deficiencies which typically occur in prior art LGA semiconductor package manufacturing processes wherein an adhesive film is peeled away from the adhesive layer used to secure a semiconductor die to the adhesive film. Further in accordance with the present invention, there is provided various methodologies which may be used to manufacture a semiconductor package having the aforementioned structural features.

The present invention is best understood by reference to the following detailed description when read in conjunction with the accompanying drawings.

### BRIEF DESCRIPTION OF THE DRAWINGS

These, as well as other features of the present invention, will become more apparent upon reference to the drawings wherein:

FIG. 1 is a cross-sectional view of a semiconductor package constructed in accordance with a first embodiment of the present invention;

FIGS. 2A-1, 2A-2, 2A-3 and 2B-2F illustrate an exemplary sequence of steps which may be used to facilitate the fabrication of the semiconductor package of the first embodiment shown in FIG. 1;

FIGS. 3A-1, 3A-2, 3A-3, and 3B-3G illustrate an exemplary sequence of steps which may be used as an alternative to those steps depicted in FIGS. 2A-1, 2A-2, 2A-3 and 2B-2F to facilitate the fabrication of a semiconductor package which is a slight variation of the first embodiment shown in FIG. 1;

FIG. 4 is a cross-sectional view of a semiconductor package constructed in accordance with a second embodiment of the present invention;

FIG. 5 is a cross-sectional view of a semiconductor package constructed in accordance with a third embodiment of the present invention;

FIG. 6 is a cross-sectional view of a semiconductor package constructed in accordance with a fourth embodiment of the present invention; and

FIGS. 7A-1, 7A-2, and 7B-7C illustrate an exemplary sequence of steps which may be used to facilitate the simultaneous fabrication of multiple semiconductor packages of the first embodiment shown in FIG. 1.

Common reference numerals are used throughout the drawings and detailed description to indicate like elements.

### DETAILED DESCRIPTION OF THE DRAWINGS

Referring now to the drawings wherein the showings are for purposes of illustrating preferred embodiments of the present invention only, and not for purposes of limiting the same, FIG. 1 illustrates a semiconductor package 100 constructed in accordance with a first embodiment of the present invention. The semiconductor package 100 comprises one or more lands 120 such land(s) 120 being embedded in a generally plate-shaped premold 130 which defines opposed, generally planar upper and lower surfaces. In the semiconductor package 100, each land 120 is positioned such that a generally planar lower surface defined thereby is exposed in the lower surface of the premold 130, and thus exposed in a lower portion of the semiconductor package 100. More particularly, as seen in FIG. 1, each land 120 is preferably embedded within the premold 130 such that the lower surface of each land 120 is substantially flush or continuous with the lower surface of the premold 130. Though not shown, the lower surface of each land 120 may have solder paste applied thereto to assist in the mounting of the semiconductor package to an underlying substrate such as a PCB or motherboard (not shown). In addition to the lower surface, each land 120 further defines a generally planar upper surface which is itself exposed in the upper surface of the premold 130. In this regard, as also seen in FIG. 1, the upper surface of each land 120 is also preferably substantially flush or continuous with the upper surface of the premold 130.

Each land 120 is preferably made of a metallic material having excellent electrical conductivity. For example, each land 120 may be fabricated from a copper plate wherein the opposed, generally planar surfaces of such plate are successively plated with nickel (Ni) and gold (Au). If each land 120 is formed by applying a nickel/gold plating layer to the opposed surfaces of a copper plate and thereafter completing a suitable etching process, it is contemplated that each land 120 will ultimately have the dumbbell or hour glass shape shown in FIG. 1. More particularly, each land will include a generally cylindrical central portion which is fabricated from copper, and opposed upper and lower end portions which each have a width exceeding that of the central portion, and define respective ones of the upper and lower surfaces of the land 120. Thus, when each land 120 is fabricated from a copper plate wherein the opposed surfaces thereof each have a nickel/gold plating layer applied thereto, it is contemplated that the upper and lower portions of each land 120 will be defined by respective ones of such plating layers, with the central portion comprising only the copper of the original copper plate. As will be recognized by those of ordinary skill in the art, imparting such dumbbell shape to each land 120 prevents each such land 120 from being easily detached from the premold 130 once embedded therein in a manner which will be described in more detail below. However, it will further be recognized that each land 120 may be provided in any one of a multiplicity of different configurations as opposed to being formed in a dumbbell shape. As indicated above, such dumbbell shape is imparted to each land 120 as a result of the completion of an etching process which will be described below. Those of ordinary skill in the art will recognize that each land 120 may be formed from other metallic materials having suitable electrical conductivity other than for those materials described above.

As indicated above, the premold 130 of the semiconductor package has a plate-like shape and defines opposed, generally planar upper and lower surfaces. Attached to the upper surface of the premold 130 is a semiconductor die 140. The attachment of the semiconductor die 140 to the upper surface of the premold 130 is preferably accomplished through the use of a layer 135 of a suitable adhesive. As also indicated above, the upper surface of the premold 130 is preferably substantially flush or continuous with the upper surface of each of the lands 120, the lower surface of the premold 130 itself being substantially flush or continuous with the lower surfaces of the lands 120. However, it is further contemplated that the lower surfaces of the lands 120 may alternatively protrude slightly from the lower surface of the premold 130. As further seen in FIG. 1, the premold 130 encapsulates the lateral surface of each of the lands 120, but not the opposed upper and lower surfaces thereof. As such, the entirety of the exposed surface of the cylindrical central portion of each land 120 is completely covered by the premold 130. The premold 130 is preferably made of an epoxy molding compound (EMC), though the present invention is not limited to any particular material for the premold 130. Further, it is contemplated that the premold 130 will preferably be formed through the completion of a transfer molding process, though the present invention is also not intended to be limited to any particular method for forming the premold 130.

As also indicated above, the semiconductor die 140 is attached to the upper surface of the premold 130 through the use of the layer 135 of the adhesive. More particularly, the semiconductor die 140 is attached in the approximate center of the upper surface of the premold 130, with the adhesive used to form the layer 135 being any one of a conventional epoxy, tape, film, or an equivalent thereto. However, the present invention is not intended to be limited to any particular adhesive material for the layer 135. Further, the layer 135 may have a sectional shape which gradually narrows upwardly as shown in FIG. 1, though alternative configurations for the layer 135 are contemplated to be within the spirit and scope of the present invention. The layer 135 is in direct contact with the upper surface of the premold 130, and also in direct contact with the generally planar lower surface of the semiconductor die 140.

In the semiconductor package 100, the semiconductor die 140 has the shape of a generally rectangular parallelepiped and defines opposed, generally planar upper and lower surfaces, the lower surface of the semiconductor die 140 being directly engaged to the layer 135 of the adhesive as indicated above. Those of ordinary skill in the art will recognize that the semiconductor die 140 may be provided in any one of a plurality of different shapes or sizes, the present invention not being limited to the specific configuration of the semiconductor die 140 shown in FIG. 1. The semiconductor die 140 includes a plurality of terminals 142 which are disposed in predetermined positions on the upper surface thereof. Each terminal 142 is typically flush or continuous with the generally planar upper surface of the semiconductor die 140, but may alternatively be slightly embedded therein and thus recessed relative thereto.

In the semiconductor package 100, the semiconductor die 140 is electrically connected to the lands 120 through the use of conductive wires 150. More particularly, each conductive wire 150 extends between a terminal 142 of the semiconductor die 140 and the upper surface of a respective one of the lands 120. Preferably, the conductive wires 150 are stitch-bonded to the terminals 142 and ball-bonded to the upper surfaces of the lands 120. For each conductive wire 150, this process is performed by forming a ball of a predetermined sized by electrical discharge on the upper surface of a corresponding land 120, thermally bonding such ball to the upper surface of the land 120 so that the ball extends therealong, and applying ultrasonic waves and heat to the corresponding terminal 142 without forming a ball. The angle between the conductive wire 150 and the upper surface of the land 120 is larger than that between the conductive wire 150 and the corresponding terminal 142. The conductive wire 150 is attached to such terminal 142 by rubbing it against the exposed surface of such terminal 142 without forming any ball. As a result, each conductive wire 150 may have a small overall height. Those of ordinary skill in the art will recognize that alternative wire bonding methods may be employed to facilitate the electrical connection of the semiconductor die 140 to the lands 150. For example, the conductive wires 150 may be ball-bonded to the terminals 142, and stitch-bonded to the lands 120. The conductive wires 150 may be conventional gold wires, aluminum wires, or equivalents thereto, the present invention not being limited to any specific material for the conductive wires 150.

The semiconductor package 100 further comprises an encapsulant or package body 160 which has a generally quadrangular configuration, and is formed so as to cover the semiconductor die 140, the conductive wires 150, and the upper surface of the premold 130 (including the upper surfaces of the lands 120). Due to the manner in which the package body 160 is preferably formed, the peripheral edge segment collectively defining the peripheral edge of the premold 130 are each preferably substantially flush or continuous with respective ones of the side surfaces defined by the fully formed package body 160. The package body 160 is preferably made of a thermosetting resin having fluidity at low temperatures, and may be formed from an epoxy molding compound, though the present invention is not intended to be limited to any specific material for the package body 160. Further, the package body 160 is preferably formed through the implementation of a transfer molding process, though those of ordinary skill in the art will recognize that alternative methods for forming the package body 160 are contemplated to be within the spirit and scope of the present invention. Since it covers the semiconductor die 140 and conductive wires 150, the package body 160 effectively protects such components from the external environment.

In the semiconductor package 100, the premold 130, which does not include a die pad, improves the peeling properties of an adhesive film (not shown) from the semiconductor package 100 subsequent to the complete fabrication of such semiconductor package 100 in a manner which will be described below. As previously explained, in currently known LGA semiconductor package fabrication processes wherein an adhesive applied to a semiconductor die is itself applied directly to adhesive film without a die pad, the removal of the adhesive film after the formation of the package body often results in a portion of the adhesive peeling off or detaching due to the strong adhesion between the adhesive film and such adhesive. The inclusion of the premold 130 guarantees easier removal of the adhesive film when such film is removed from the semiconductor package 100 subsequent to the formation of the package body 160, such ease of detachability resulting from the reduced level of adhesion between the adhesive film and the lower surface of the premold 130. As a result, the adhesive film is removed from the lower surface of the premold 130 without a trace, thus resulting in the semiconductor package 100 being of substantially uniform thickness. The premold 130 is made of an insulating material so that the semiconductor package 100 can be mounted thereon regardless of whether or not a conductive pattern or passive device is formed on the upper surface of the underlying motherboard.

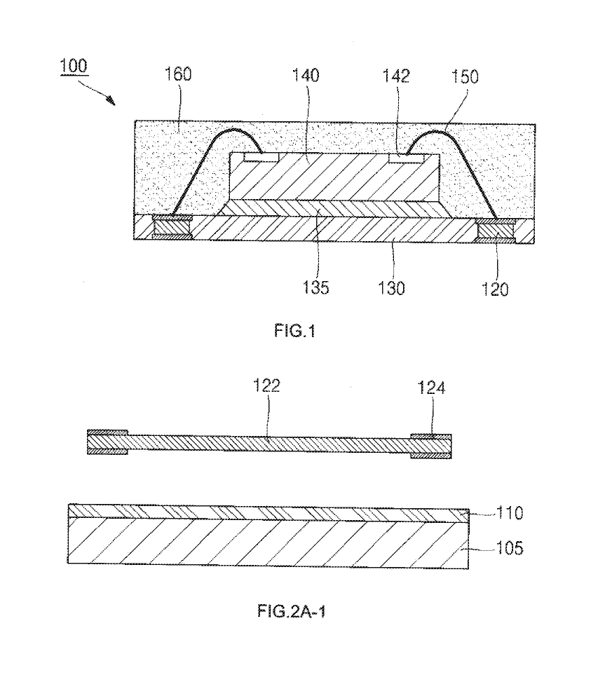

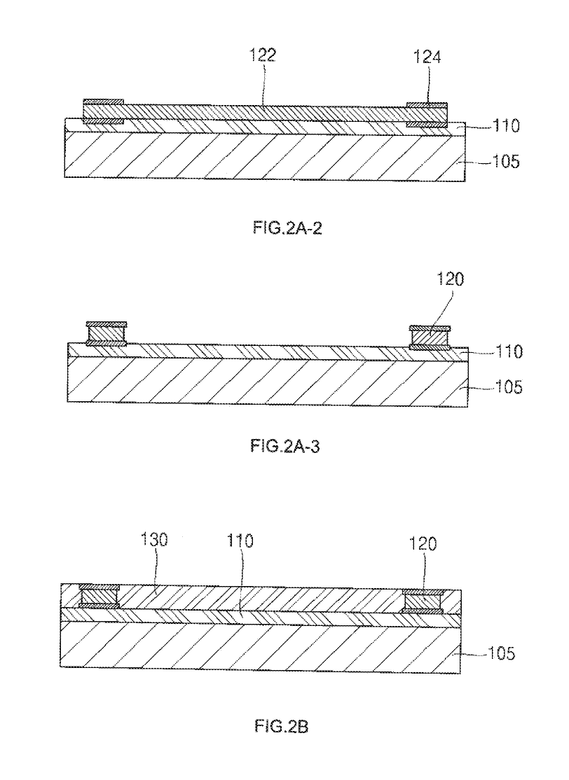

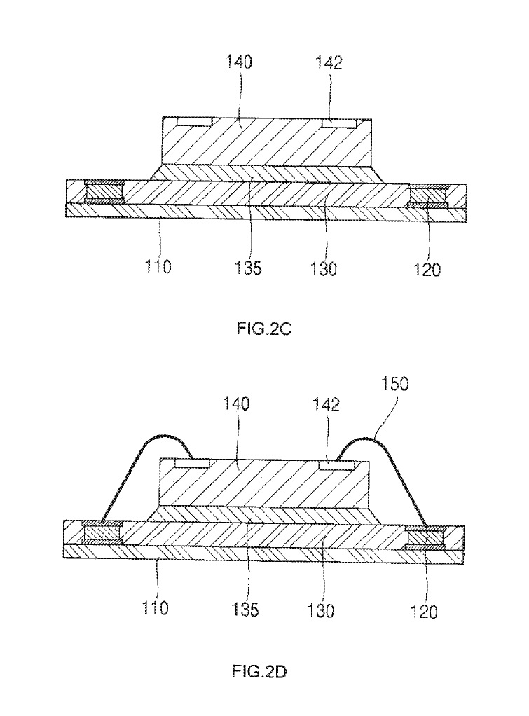

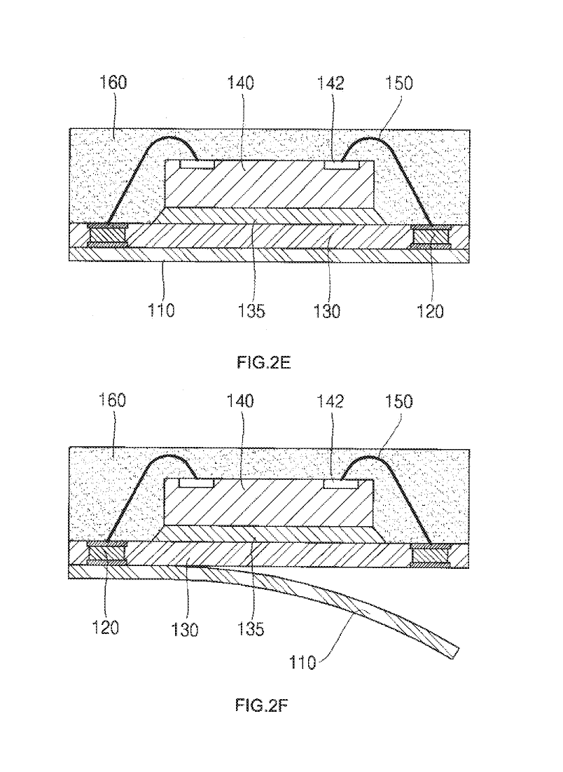

Referring now to FIGS. 2A-2F, there is illustrated an exemplary sequence of steps which may be used to facilitate the formation of the semiconductor package 100 shown in FIG. 1. In the initial step of the fabrication process, a flat copper plate 122 is provided. Applied to selected portions of each of the opposed, generally planar upper and lower surfaces of the copper plate 122 is a masking layer which may comprise a dry film. Subsequent to the application of the masking layer to the copper plate 122, a nickel/gold layer is plated onto the unmasked portion of each of the opposed surfaces of the copper plate 122. More particularly, a gold layer is first plated onto each of the opposed surfaces of the copper plate 122, the application of the gold layer being followed by plating a nickel layer onto each gold layer. Subsequent to the formation of the combined nickel/gold layer, the masking layer may be removed, thus resulting in the copper plate 122 including a plurality of separate and distinct plating layers 124 upon prescribed locations of each of the opposed upper and lower surfaces thereof, as shown in FIG. 2A-1. More particularly, as shown, each plating layer 124 formed on one surface of the copper plate 122 is substantially aligned with a corresponding plating layer 124 formed on the opposite surface of the copper plate 122. Those of ordinary skill in the art will recognize that each plating layer 124 may be formed by plating metals other than the nickel and gold metals described above, alternative metals of suitable electrical conductivity being contemplated to be within the spirit and scope of the present invention.

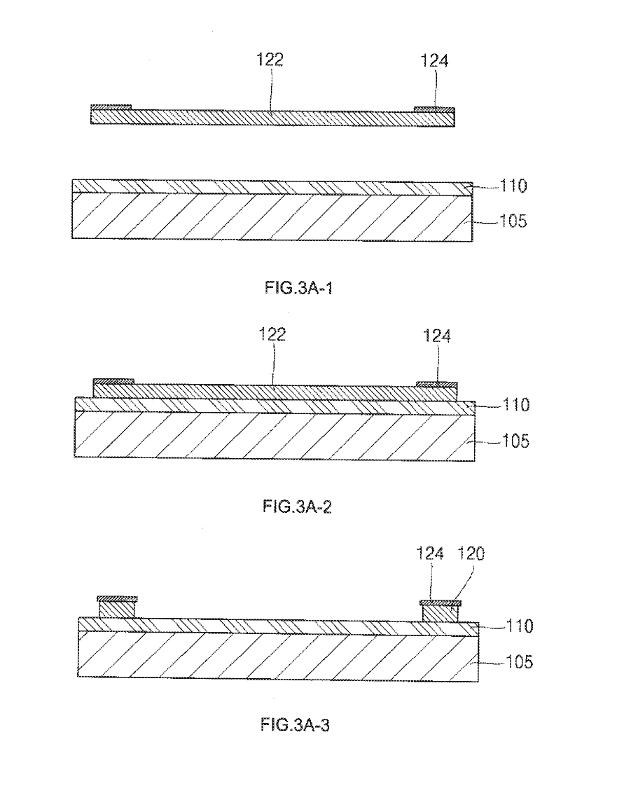

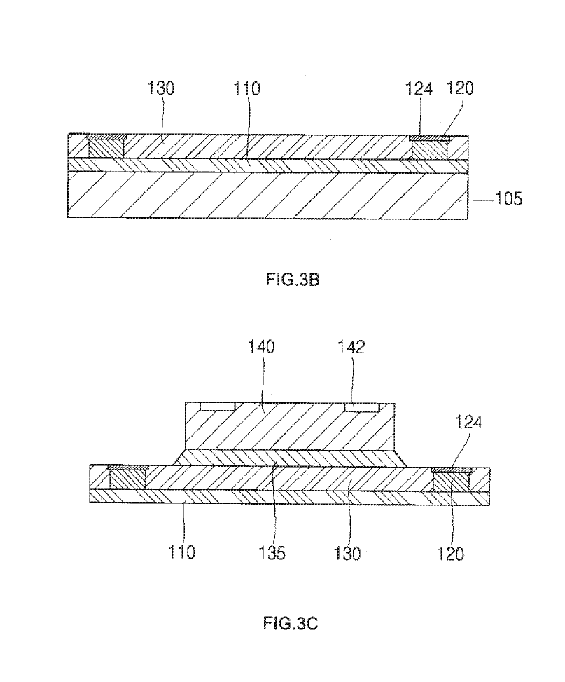

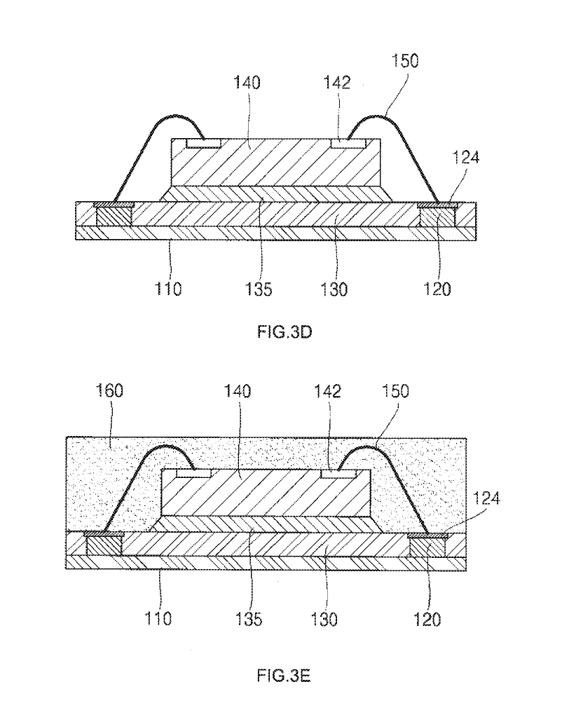

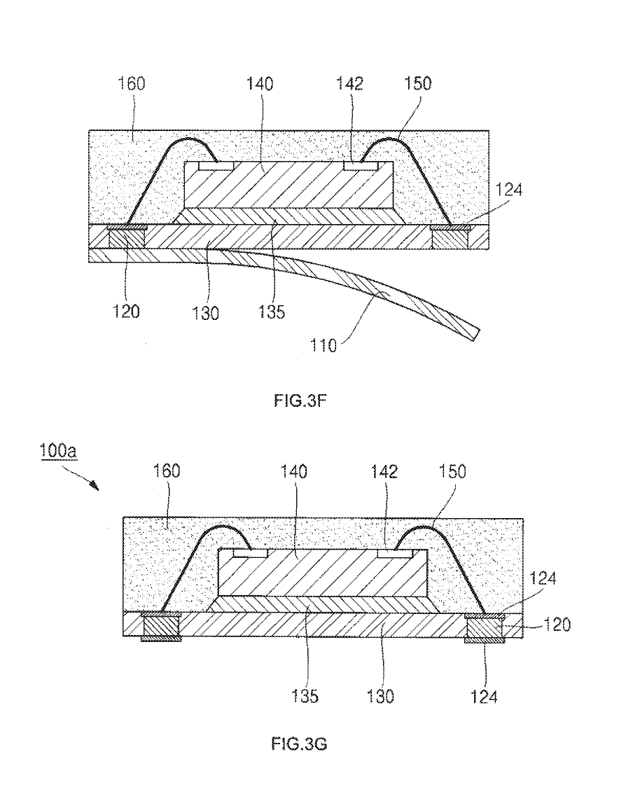

In the next step of the fabrication process for the semiconductor package 100, the lower surface of the copper plate 122 is attached or laminated to the upper surface of an adhesive film 110 which is itself applied to the upper surface of a carrier 105, as shown in FIG. 2A-2. In this regard, the lowermost surfaces of the plating layers 124, as well as the lower surface of the copper plate 132, are each laminated to and thus covered by the adhesive film 110. Thereafter, as shown in FIG. 2A-3, an etching method or process is completed which effectively removes those portions of the copper plate 122 other than those which are disposed between corresponding aligned pairs of the plating layers 124. As will be recognized, the completion of such etching process effectively forms each of the lands 120. In this regard, each such land 120 has the above-described dumbbell shape including a generally cylindrical central portion which is fabricated from the copper of the copper plate 122, and opposed upper and lower end portions which each have a width exceeding that of the central portion and define respective ones of the upper and lower surfaces of the land 120. As indicated above, such upper and lower portions of each land 120 are defined by respective ones of each corresponding, aligned pair of the plating layers 124. Thus, one plating layer 124 of the land 120 defined the upper surface thereof, with the remaining plating layer 124 of the land 120 defining the lower surface thereof. As further seen in FIG. 2A-3, in each land 120, the lower surfaces of those plating layers 124 defining the lower portions of each land 120 remain covered by the adhesive film 110 subsequent to the completion of the etching process. It is contemplated that the aforementioned etching process may be completed through the use of a copper sulfate (CuSO₄) solution, an alkaline series, an ammonia series, or similar materials as an etching liquid. In this regard, the present invention is not intended to be limited to any particular type of etching liquid to be used in the completion of the above-described etching process.

Referring now to FIG. 2B, subsequent to the completion of the etching process to form the lands 120, the above-described transfer molding process using an epoxy molding compound is completed to facilitate the formation of the premold 130. As shown in FIG. 2B, the premold 130 is formed to cover the exposed portions of the upper surface of the adhesive film 110, as well as the lateral surfaces of each land 120. In this regard, not covered by the premold 130 is the upper surface of each land 120, or the lower surface thereof which is directly engaged to and thus covered by the underlying adhesive film 110. Thus, the thickness of the premold 130 (i.e., the distance between the opposed upper and lower surfaces thereof) is substantially the same as the thickness of each land 120 (i.e., the distance separating the opposed upper and lower surfaces thereof). As a result, as explained above, the upper surfaces of the lands 120 extend in substantially flush or continuous relation with the upper surface of the fully formed premold 130, with the lower surfaces of the lands 120 extending in substantially flush or continuous relation with the lower surface of the fully formed premold 130. However, those of ordinary skill in the art will recognize that the upper surface of the premold 130 may alternatively be elevated or recessed relative to the upper surfaces of the lands 120, rather than being substantially flush therewith. Similarly, the lower portions of the lands 120 may be slightly embedded within the adhesive film 110 such that, in the fully formed semiconductor package 100, the lower portions of the lands 120 and hence the lower surfaces defined thereby protrude slightly from the lower surface of the premold 130. Regardless of the design of the semiconductor package 100 and the thickness of the lands 120 thereof, it is contemplated that the premold 130 may be formed through the use of a conventional flat mold chase.

Referring now to FIG. 2C, subsequent to the formation of the premold 130, the semiconductor die 140 is attached to the central portion of the upper surface of the premold 130 through the use of the layer 135 of the adhesive in the above-described manner. As previously mentioned, the layer 135 may be applied to the premold 130 in a manner such that it gradually narrows upwards in the manner shown in FIG. 2C.

As seen in FIG. 2D, after the semiconductor die 140 has been attached to the premold 130 through the use of the layer 135 of the adhesive, the terminals 142 of the semiconductor die 140 are electrically connected to the upper surfaces of the lands 120 through the use of the conductive wires 150 in the manner described above. As previously explained, the wire bonding process may be completed by exposing a conductive wire 150 of a predetermined length from a capillary, forming a ball with predetermined sized on the upper surface of a corresponding land 120 by electrical discharge, fastening such ball to the land 120, transmitting energy from the capillary through ultrasonic vibration and heat to complete a ball bonding process to the land 120, looping the conductive wire 150 until it reaches a respective terminal 142 of the semiconductor die, and again applying ultrasonic vibration and heat while rubbing the tip of the capillary against the surface of such terminal 142 to complete the stitch bonding of the conductive wire 150 thereto. As also previously mentioned, the wire bonding process may also be performed by ball-bonding each conducive wire 150 to a respective terminal 142, and thereafter stitch-bonding the conductive wire 150 to the upper surface of the corresponding land 120.

Referring now to FIG. 2E, the completion of the above-described wire bonding process is followed by the formation of the package body 160 in the above-described manner. As indicated above, the package body 160 is preferably formed through the completion of a transfer molding process using, for example, an epoxy molding compound. The fully formed package body 160 covers the upper surface of the premold 130, as well as the semiconductor die 140 and the conductive wires 150. The package body 160 is formed to be of a predetermined thickness so that there is prescribed distance separating the upper surface of the package body 160 from the highest portion of each of the conductive wires 150.

Referring now to FIG. 2F, upon the formation of the package body 160, the adhesive film 110 is peeled away from the lower surface of the premold 130, thus completing the formation of the semiconductor package 100. Since the premold 130 and the adhesive layer 110 are made of different materials, the adhesive film 110 is easily removed (i.e., peeled away) from the premold 130, with the lower surface of the premold 130 being substantially smooth and the thickness of the semiconductor package 100 being substantially uniform. The completed semiconductor package 100 is of reduced thickness due to the absence of any die pad therein. However, despite the absence of such die pad, the adhesive film 110 is easily removed therefrom since such adhesive film 110 is originally disposed on and subsequently peeled from the lower surface of the premold 130, as opposed to being in direct contact with the layer 135 of the adhesive. Thus, the inclusion of the premold 130 in the semiconductor package 100 eliminates many of the drawbacks described above in relation to the currently known processes for fabricating LGA semiconductor packages which do not include a die pad.

Referring now to FIGS. 3A-3F, there is illustrated an exemplary sequence of steps which may be used to facilitate the formation of the semiconductor package 100a shown in FIG. 3G which comprises a slight variation of the semiconductor package 100 shown in FIG. 1. In this regard, the distinction between the semiconductor packages 100, 100a lies in the lower surfaces of the lands 120 in the semiconductor package 100a extending along a common plane which is disposed in spaced, generally parallel relation to the plane along which the lower surface of the premold 130 extends. Thus, the lower surfaces of the lands 120 in the semiconductor package 100a are disposed outwardly relative to the lower surface of the premold 130 rather than extending in substantially coplanar thereto as in the semiconductor package 100. In the initial step of the fabrication process for the semiconductor package 100a, a flat copper plate 122 is provided. Applied to a selected portion of the generally planar upper surface of the copper plate 122 is a masking layer which may comprise a dry film. Subsequent to the application of the masking layer to the copper plate 122, a nickel/gold layer is plated onto the unmasked portion of the upper surface of the copper plate 122. More particularly, a gold layer is first plated onto the upper surface of the copper plate 122, the application of the gold layer being followed by plating a nickel layer onto the gold layer. Subsequent to the formation of the combined nickel/gold layer, the masking layer may be removed, thus resulting in the copper plate 122 including a plurality of separate and distinct plating layers 124 upon prescribed locations of the upper surface thereof, as shown in FIG. 3A-1. Those of ordinary skill in the art will recognize that each plating layer 124 may be formed by plating metals other than the nickel and gold metals described above, alternative metals of suitable electrical conductivity being contemplated to be within the spirit and scope of the present invention.

In the next step of the fabrication process for the semiconductor package 100, the lower surface of the copper plate 122 is attached or laminated to the upper surface of an adhesive film 110 which is itself applied to the upper surface of a carrier 105, as shown in FIG. 3A-2. Thereafter, as shown in FIG. 3A-3, an etching method or process is completed which effectively removes those portions of the copper plate 122 other than those which are disposed underneath respective ones of the plating layers 124. As will be recognized, the completion of such etching process effectively forms a substantial portion of each of the lands 120. In this regard, each land 120 formed by the completion of the etching process includes a generally cylindrical central portion which is fabricated from the copper of the copper plate 122, and an upper end portion which has a width exceeding that of the central portion and defines the upper surface of the land 120. As indicated above, such upper portion of each land 120 is defined by one of the plating layers 124. As further seen in FIG. 3A-3, in each land 120, that end of the central portion not having the plating layer 124 formed thereon remains covered by the adhesive film 110 subsequent to the completion of the etching process. It is contemplated that the aforementioned etching process may be completed through the use of a copper sulfate (CuSO₄) solution, an alkaline series, an ammonia series, or similar materials as an etching liquid. In this regard, the present invention is not intended to be limited to any particular type of etching liquid to be used in the completion of the above-described etching process.

Referring now to FIG. 3B, subsequent to the completion of the etching process to partially form the lands 120, the above-described transfer molding process using an epoxy molding compound is completed to facilitate the formation of the premold 130. As shown in FIG. 3B, the premold 130 is formed to cover the exposed portions of the upper surface of the adhesive film 110, as well as the lateral surfaces of each land 120. In this regard, not covered by the premold 130 is the upper surface of each land 120, or the lower end of the central portion thereof which is directly engaged to and thus covered by the underlying adhesive film 110. Thus, the thickness of the premold 130 (i.e., the distance between the opposed upper and lower surfaces thereof) is substantially the same as the thickness of each partially formed land 120 (i.e., the distance separating the upper surface defined by the plating layer 124 thereof from the lower end of the corresponding central portion). As a result, the upper surfaces of the lands 120 extend in substantially flush or continuous relation with the upper surface of the fully formed premold 130, with the generally planar lower ends of the central portions of the lands 120 extending in substantially flush or continuous relation with the lower surface of the fully formed premold 130. However, those of ordinary skill in the art will recognize that the upper surface of the premold 130 may alternatively be elevated or recessed relative to the upper surfaces of the lands 120, rather than being substantially flush therewith. Regardless of the design of the semiconductor package 100 and the thickness of the lands 120 thereof, it is contemplated that the premold 130 may be formed through the use of a conventional flat mold chase.

Referring now to FIG. 3C, subsequent to the formation of the premold 130, the semiconductor die 140 is attached to the central portion of the upper surface of the premold 130 through the use of the layer 135 of the adhesive in the above-described manner. As previously mentioned, the layer 135 may be applied to the premold 130 in a manner such that it gradually narrows upwards in the manner shown in FIG. 3C. As seen in FIG. 3D, after the semiconductor die 140 has been attached to the premold 130 through the use of the layer 135 of the adhesive, the terminals 142 of the semiconductor die 140 are electrically connected to the upper surfaces of the lands 120 through the use of the conductive wires 150 in the same manner described above in relation to FIG. 2D.

Referring now to FIG. 3E, the completion of the above-described wire bonding process is followed by the formation of the package body 160 in the above-described manner. As indicated above, the package body 160 is preferably formed through the completion of a transfer molding process using, for example, an epoxy molding compound. The fully formed package body 160 covers the upper surface of the premold 130, as well as the semiconductor die 140 and the conductive wires 150. The package body 160 is formed to be of a predetermined thickness so that there is prescribed distance separating the upper surface of the package body 160 from the highest portion of each of the conductive wires 150.

Referring now to FIG. 3F, upon the formation of the package body 160, the adhesive film 110 is peeled away from the lower surface of the premold 130, thus exposing the bottom surface of the premold 130 and the lower ends of the central portions of the partially formed lands 120. Since the premold 130 and the adhesive layer 110 are made of different materials, the adhesive film 110 is easily removed (i.e., peeled away) from the premold 130, with the lower surface of the premold 130 being substantially smooth and the thickness of the semiconductor package 100a being substantially uniform.

Referring now to FIG. 3G, subsequent to the removal of the adhesive film 110 from the premold 130 in the above-described manner, another plating process is completed wherein a nickel/gold layer is plated onto the exposed lower end of the central portion of each partially formed land 120. More particularly, a gold layer is first plated onto the exposed lower end of each central portion, the application of the gold layer being followed by plating a nickel layer onto each gold layer. The combined nickel/gold layer defines a separate and distinct plating layer 124 upon the lower end of each central portion of each land 120. As shown in FIG. 3G, each plating layer 124 formed on the lower end of a respective central portion is substantially aligned with the corresponding plating layer 124 formed on the opposed upper end thereof. Thus, when each land 120 is fully fabricated, it is contemplated that the upper and lower portions and hence the upper and lower surfaces of each land 120 will be defined by respective ones of the corresponding plating layers 124, with the central portion comprising only the copper of the original copper plate 122. The formation of the plating layers 124 on the lower ends of the central portions completes the formation of the lands 120 and the formation of the semiconductor package 100a as well.

Due to the widths of the plating layers 124 of each land 120 each exceeding the maximum width of the central portion extending therebetween, each land 120 of the semiconductor package 100a also has a generally dumbbell shape. However, it will further be recognized that each land 120 may be provided in any one of a multiplicity of different configurations as opposed to being formed in a dumbbell shape, and further may be formed from other metallic materials having suitable electrical conductivity other than for those materials described above. As indicated above, the distinction between the semiconductor packages 100, 100a lies in the lower surfaces of the lands 120 in the semiconductor package 100a extending along a common plane which is disposed in spaced, generally parallel relation to the plane along which the lower surface of the premold 130 extends. Thus, the lower surfaces of the lands 120 in the semiconductor package 100a are disposed outwardly relative to the lower surface of the premold 130 rather than extending in substantially coplanar thereto as in the semiconductor package 100. The completed semiconductor package 100a is of reduced thickness due to the absence of any die pad therein. Despite the absence of a die pad in the semiconductor package 100a, the adhesive film 110 is easily removed from the premold 130 since such adhesive film 110 is originally disposed on and subsequently peeled from the lower surface of the premold 130, as opposed to being in direct contact with the layer 135 of the adhesive. Thus, the inclusion of the premold 130 in the semiconductor package 100a eliminates many of the drawbacks described above in relation to the currently known processes for fabricating LGA semiconductor packages which do not include a die pad.

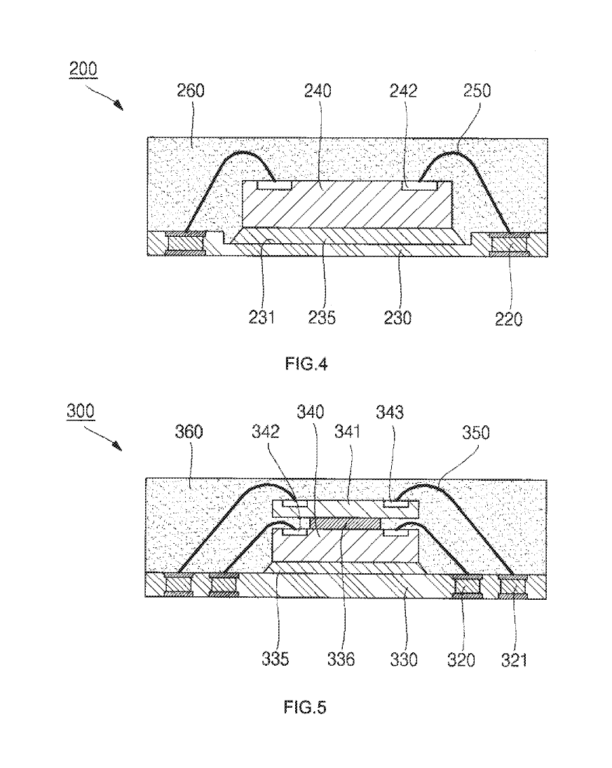

Referring now to FIG. 4, there is shown a semiconductor package 200 constructed in accordance with a second embodiment of the present invention. The semiconductor package 200 of the second embodiment bears substantial similarity in construction to the semiconductor package 100 of the first embodiment, with the 200 series reference numerals in FIG. 4 being used to identify the same structures identified by the corresponding 100 series reference numerals included in FIG. 1. In this regard, only the distinctions between the semiconductor packages 200, 100 will be discussed below.

The distinction between the semiconductor packages 200, 100 lies in the inclusion of a recess 231 within the approximate center of the upper surface of the premold 230 of the semiconductor package 200. In this regard, the layer 235 of the adhesive is used to secure the semiconductor die 240 to the lowermost surface of the recess 231 in the manner shown in FIG. 4. Due to the inclusion of the recess therein, the premold 230 does not define a generally planar upper surface, but rather includes a peripheral portion which extends along a plane elevated relative to the plane along which the lowermost surface of the recess 231 extends. The thickness of the premold 230 between the lowermost surface of the recess 231 and the lower surface of the premold 230 may vary depending on the prescribed overall thickness of the semiconductor package 200. As will be recognized, due to the inclusion of the recess 231 in the premold 230, the semiconductor package 200 may be fabricated to be of reduced thickness relative to the above-described semiconductor package 100.

Referring now to FIG. 5, there is shown a semiconductor package 300 constructed in accordance with a third embodiment of the present invention. The semiconductor package 300 of the third embodiment bears similarity in construction to the semiconductor package 100 of the first embodiment, with the 300 series reference numerals in FIG. 5 being used to identify the same structures identified by the corresponding 100 series reference numerals included in FIG. 1. In this regard, only the distinctions between the semiconductor packages 300, 100 will be discussed below.

One distinction between the semiconductor packages 300, 100 lies in the arrangement of the lands in the semiconductor package 300. More particularly, in the semiconductor package 100 (as well as the semiconductor package 200), the lands 120 are arranged in a single row which fully or at least partially circumvents the semiconductor die 140. While the semiconductor package 300 includes the lands 320 which are also arranged in a row fully or at least partially circumventing the semiconductor die 340, also included in the semiconductor package 300 are lands 321 which are identically configured to the lands 320 and are arranged in a row which fully or at least partially circumvents the lands 320. Thus, in the semiconductor package 300, the lands 320, 321, while being identically configured to each other and formed in the same manner, are segregated or arranged as inner and outer rows which are disposed in spaced relation to each other. It is contemplated that each land 321 of the outer row may be aligned with a respective land 320 of the inner row, or that the lands 320, 321 of the inner and outer rows may be arranged in a staggered or offset relationship relative to each other.

A further distinction between the semiconductor packages 300, 100 lies in the inclusion of a second semiconductor die 341 in the semiconductor package 300, such second semiconductor die 341 being stacked upon and secured to the semiconductor die 340. More particularly, as seen in FIG. 5, a layer 336 of a suitable adhesive is used to secure the generally planar lower surface of the second semiconductor die 341 to the central portion of the generally planar upper surface of the underlying semiconductor die 340. Like the semiconductor die 340, the second semiconductor die 341 includes a plurality of terminals 343 disposed within the peripheral portion of the upper surface thereof. In the semiconductor package 300, conductive wires 350 are used to electrically connect the terminals 343 to respective ones of the lands 321. Thus, while the conductive wires 350 are used to electrically connect the terminals 342 of the semiconductor die 340 to respective ones of the lands 320, such conductive wires 350 are also used to electrically connect the terminals 343 of the second semiconductor die 341 stacked upon the semiconductor die 340 to respective ones of the lands 321. Those of ordinary skill in the art will recognize that stitch-bonding and/or ball-bonding processes may be used to facilitate the interface of the conductive wires 350 to the terminals 343 and lands 321 in the same manner described above in relation to the semiconductor package 100 of the first embodiment of the present invention. Additionally, it will be recognized that alternative patterns of electrical connection between the semiconductor dies 340, 341 and lands 320, 321 differing from that shown in FIG. 5 are contemplated to be within the spirit and scope of the present invention. For example, each semiconductor die 340, 341 may be electrically connected through the use of the conductive wires 350 to one or more of the lands 320 and/or one more of the lands 321.

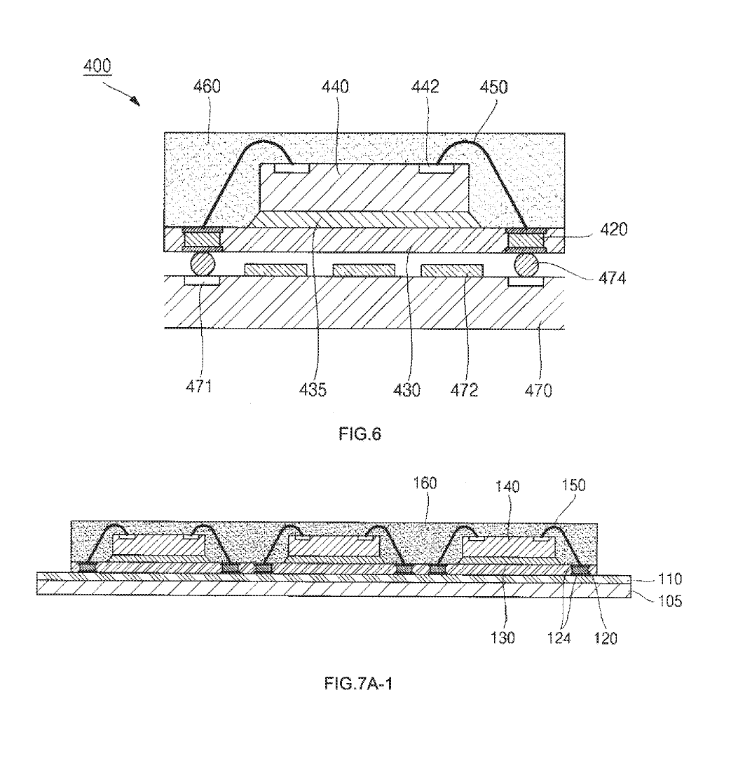

Referring now to FIG. 6, there is shown a semiconductor package 400 constructed in accordance with a fourth embodiment of the present invention. The semiconductor package 400 of the fourth embodiment bears substantial similarity in construction to the semiconductor package 100 of the first embodiment, with the 400 series reference numerals in FIG. 6 being used to identify the same structures identified by the corresponding 100 series reference numerals included in FIG. 1. In this regard, only the distinctions between the semiconductor packages 400, 100 will be discussed below.

The sole distinction between the semiconductor packages 400, 100 lies in the addition of a solder ball 474 on the lower surface of each land 420 within the semiconductor package 400. The solder balls 474 are used to facilitate the electrical connection of the semiconductor package 400 to an underlying substrate such as the motherboard 470 shown in FIG. 6. In this regard, the solder balls 474 are electrically connected to a conductive pattern 471 disposed on the motherboard 470, with the clearance between the upper surface of the motherboard 470 and the lower surface of the premold 430 provided by the solder balls 474 creating sufficient space to accommodate one or more passive devices 472 disposed on the upper surface of the motherboard 470 as well. Since the premold 430 of the semiconductor package 400 is made of an insulating substance or material, there is no danger of any short circuiting between the semiconductor package 400 and such passive devices 472 even if the semiconductor package 400 makes contact therewith. As indicated above, the inclusion of the solder balls 474 provides sufficient space or clearance allowing for the mounting of the passive devices 472 upon that surface of the motherboard 470 to which the semiconductor package 400 is electrically connected, such passive devices 472 being disposed underneath the semiconductor package 400 if so desired.

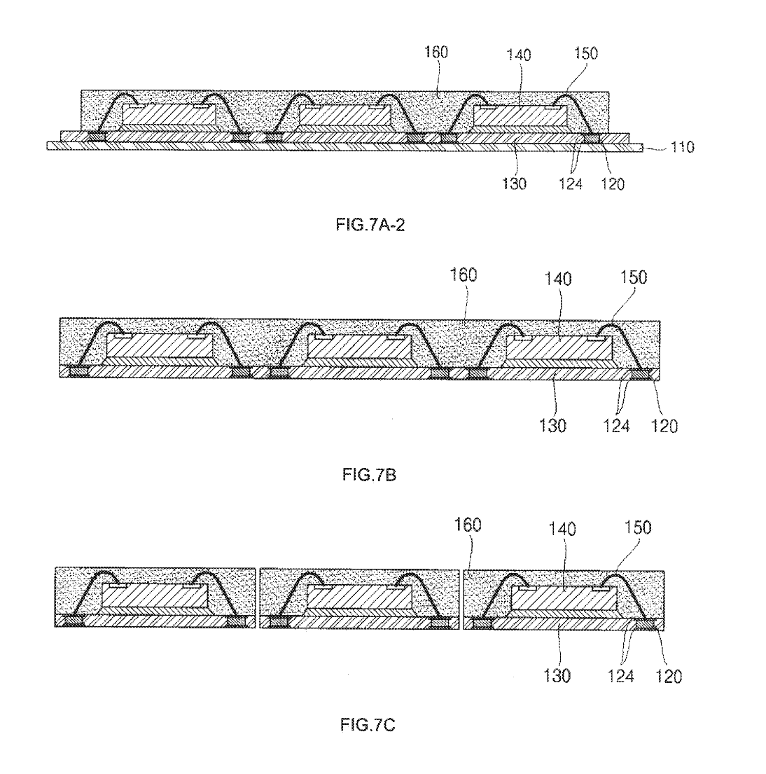

Referring now to FIGS. 7A-7C, there is shown an exemplary sequence of steps which may be used to facilitate the simultaneous fabrication of multiple semiconductor packages 100. The process for simultaneously manufacturing multiple semiconductor packages 100 essentially follows the same process described above in relation to FIGS. 2A-2F except that, as seen in FIG. 7A-1, both the carrier 105 and the adhesive film 110 applied to the upper surface thereof are suitably size so as to allow for the formation of a premold assembly thereon, such premold assembly comprising a plurality of integrally connected premolds 130. Subsequent to the formation of such premold assembly through the implementation of essentially the same steps described above in relation to FIGS. 2A-1, 2A-2, 2A-3 and 2B, the die attach step described above in relation to FIG. 2C, and the wire bonding step described above in relation to FIG. 2D are each carried out in relation to each of the individual premolds 130 defined by the premold assembly. Thereafter, an encapsulation step similar to that described in relation to FIG. 2E is completed to form a continuous mold cap which covers all of the semiconductor dies 140 and conductive wires 150 attached to the premold assembly, as well as the entirety of the upper surface of the premold assembly. As will be recognized, such mold cap, once singulated in a manner which will be described in more detail below, will define the individual package bodies 160 of the completed semiconductor packages 100. As seen in FIG. 7A-2, it is contemplated that a secondary, frame-like carrier 106 may be applied to the upper surface of the adhesive film 110, such carrier 106 circumventing the premold assembly.

Subsequent to the formation of the mold cap, the adhesive film 110 is peeled away or otherwise removed from the lower surface of the premold assembly. Subsequent to the removal of the adhesive film 110 (as well as the carriers 105, 106), a singulation process is completed to effectively define the separate semiconductor packages 100 in the manner shown in FIG. 7C. Such singulation is preferably accomplished by sawing, the saw blade being advanced through the mold cap and the premold assembly in a pattern which effectively separates the mold cap and the premold assembly into the separate semiconductor packages 100. As will be recognized, during the saw singulation process, the saw blade(s) are not passing through any metal material, but rather only the insulative material of the premold assembly and mold cap. The completion of the saw singulation process effectively separates the premold assembly into the separate premolds 130 and into the separate package bodies 160, as described above. Those of ordinary skill in the art will recognize that that this gang fabrication process is also applicable to the other embodiments of the semiconductor package described herein.

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process may be implemented by one of skill in the art in view of this disclosure.

What is claimed is:

1-20. (canceled)

21. A method for forming a semiconductor package comprising:
providing a premold substrate comprising:
a first conductive portion having a side surface at least partially encapsulated with a molded insulating material;
a second conductive portion having a surface exposed to the outside of the molded insulating material;
electrically connecting a semiconductor die to the second conductive portion; and
forming a package body covering at least the semiconductor die and at least a portion of the surface of the second conductive portion exposed to the outside of the molded insulating material.

22. The method of claim 21, wherein providing the premold substrate comprises:
providing the first conductive portion having a first width; and
providing the second conductive portion having a second width greater than the first width.

23. The method of claim 21, wherein providing the premold substrate comprises:
providing the first conductive portion comprising a first material; and
providing the second conductive portion comprising a second material.

24. The method of claim 21, wherein providing the premold substrate comprises:
providing a conductive substrate comprising a first conductive material and having generally planar upper and lower surfaces;
selectively forming the second conductive portion on the upper surface;
attaching the lower surface of the conductive substrate to a support substrate;
removing portions of the conductive substrate leaving a remaining portion of the conductive substrate to provide the first conductive portion adjoining the second conductive portion;
thereafter providing the molded insulating material; and
removing the support substrate.

25. The method of claim 21, wherein providing the premold substrate comprises providing the second conductive portion having an upper surface exposed to the outside of the molded insulating material.

26. The method of claim 21, wherein providing the premold substrate comprises providing the second conductive portion having a top surface exposed to the outside of the molded insulating material.

27. The method of claim 21, wherein providing the premold substrate comprises providing the second conductive portion extending to a lower surface of the premold substrate.

28. The method of claim 27, wherein providing the premold substrate further comprises providing a third conductive portion contiguous with the lower surface of the premold substrate and contiguous with the second conductive portion.

29. The method of claim 21, wherein providing the premold substrate comprises:
providing the first conductive portion at least partially encapsulated with an epoxy mold compound formed using a transfer mold process; and
providing the premold substrate devoid of a die attach pad.

30. The method of claim 21, wherein electrically connecting the semiconductor die comprises:
attaching the semiconductor die to the premold substrate; and
electrically connecting the semiconductor die to the second conductive portion with a conductive connective structure.

31. A method for forming a semiconductor package comprising:
providing a premolded substrate comprising:
a first conductive portion having an insulating material molded onto a side surface of the first conductive portion; and
a second conductive portion having a surface exposed to the outside of the insulating material;
electrically coupling a semiconductor die to the second conductive portion; and
forming a package body covering at least the semiconductor die, at least a portion of the semiconductor die, and at least a portion of the second conductive portion surface exposed to the outside of the insulating material.

32. The method of claim 31, wherein providing the premolded substrate comprises:
providing an epoxy mold compound molded onto the side surface of the first conductive portion using a transfer molding process; and
providing the epoxy mold compound comprises providing the epoxy mold compound recessed relative to an upper surface of the second conductive portion.

33. The method of claim 31, wherein providing the premolded substrate comprises:
providing the first conductive portion having a first width; and
providing the second conductive portion having a second width greater than the first width.

34. The method of claim 31, wherein providing the premolded substrate comprises providing the second conductive portion having an upper surface exposed to the outside of the insulating material.

35. The method of claim 31, wherein providing the premolded substrate comprises:
providing a conductive substrate comprising a first conductive material and having generally planar upper and lower surfaces;
selectively forming the second conductive portion on the upper surface;
attaching the lower surface of the conductive substrate to a support substrate;
removing portions of the conductive substrate leaving a remaining portion of the conductive substrate to provide the first conductive portion affixed to the second conductive portion;
thereafter molding the insulating material onto the side surface of the first conductive portion; and
removing the support substrate.

36. A method for forming a semiconductor package comprising:
providing a substrate premolded with a mold compound comprising:
a first conductive portion having the mold compound molded onto at least a side surface of the first conductive portion; and
a second conductive portion having a surface exposed to the outside of the mold compound;
electrically coupling a semiconductor die to the second conductive portion; and
forming a package body covering at least the semiconductor die and at least a portion of the semiconductor die and at least a portion of the second conductive portion surface exposed to the outside of the mold compound.

37. The method of claim 36, wherein providing the substrate comprises:
providing the first conductive portion having a first width; and
providing the second conductive portion having a second width greater than the first width.

38. The method of claim 31, wherein providing the substrate comprises providing the second conductive portion having an upper surface exposed to the outside of the mold compound.

39. The method of claim 31, wherein providing the substrate comprises providing the second conductive portion having a top surface exposed to the outside of the mold compound.

40. The method of claim 31, wherein providing the substrate comprises:
providing a conductive substrate having generally planar upper and lower surfaces;
selectively forming the second conductive portion on the upper surface;
attaching the lower surface of the conductive substrate to a support substrate;
removing portions of the conductive substrate to form the first conductive portion; and
molding the mold compound to the side surface of the first conductive portion.
